(19) United States
(12) Patent Application Publication
(10) Pub. No.: US 2024/0097039 A1
(43) Pub. Date: Mar. 21, 2024

(54) Crystallization of High-K Dielectric Layer

(71) Applicant: Taiwan Semiconductor Manufacturing Co., Ltd., Hsinchu (TW)

(72) Inventor: Chien-Chang CHEN, New Taipei City (TW)

(73) Assignee: Taiwan Semiconductor Manufacturing Co., Ltd., Hsinchu (TW)

(21) Appl. No.: 18/188,314

(22) Filed: Mar. 22, 2023

Related U.S. Application Data
(60) Provisional application No. 63/375,885, filed on Sep. 16, 2022.

(51) Int. Cl. H01L 29/78; H01L 21/8238; H01L 27/092; H01L 29/06; H01L 29/423; H01L 29/66; H01L 29/775; H01L 29/786

(52) U.S. Cl. CPC H01L 29/7851; H01L 21/823807; H01L 21/823821; H01L 27/0924; H01L 29/0673; H01L 29/42392; H01L 29/66439; H01L 29/66795; H01L 29/775; H01L 29/78696

(57) ABSTRACT

The present disclosure describes a semiconductor device having a crystalline high-k dielectric layer. The semiconductor structure includes a fin structure on a substrate, a gate dielectric layer on the fin structure, and a gate structure on the gate dielectric layer. A top portion of the gate dielectric layer is crystalline and includes a crystalline high-k dielectric material.

### CROSS-REFERENCE TO RELATED APPLICATIONS

The present application claims the benefit of U.S. Provisional Patent Appl. No. 63/375,885, titled “Crystallization of High-k Film,” and filed on Sep. 16, 2022, which is incorporated herein by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes and increased the difficulty of defects control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having a crystalline high-k dielectric layer, in accordance with some embodiments.

FIGS. 2-4 illustrate cross-sectional views of a semiconductor device having a crystalline high-k dielectric layer, in accordance with some embodiments.

FIG. 5 is a flow diagram of a method for fabricating a semiconductor device having a crystalline high-k gate dielectric layer, in accordance with some embodiments.

FIGS. 6-21 illustrate cross-sectional views of a semiconductor device having a crystalline high-k gate dielectric layer at various stages of its fabrication, in accordance with some embodiments.

FIG. 22 is a flow diagram of a method for fabricating another semiconductor device having a crystalline high-k gate dielectric layer, in accordance with some embodiments.

FIGS. 23-29 illustrate cross-sectional views of another semiconductor device having a crystalline high-k gate dielectric layer, in accordance with some embodiments.

FIG. 30 is a flow diagram of a method for fabricating yet another semiconductor device having a crystalline high-k dielectric layer in a gate isolation structure, in accordance with some embodiments.

FIGS. 31-34 illustrate cross-sectional views of yet another semiconductor device having a crystalline high-k dielectric layer in a gate isolation structure, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, gate dielectric layers can include high-k dielectric material to reduce dimensions and increase gate control. The term “high-k” can refer to a high dielectric constant. In the field of semiconductor device structures and manufacturing processes, high-k can refer to a dielectric constant that is greater than the dielectric constant of silicon oxide (e.g., greater than about 3.9). The high-k dielectric material in gate dielectric layers include both amorphous and crystalline phases after formation. The crystallization of the high-k dielectric material can be non-uniform due to different levels of doping and a subsequent anneal during metal gate formation. Boundaries of the amorphous and crystalline high-k dielectric material can form leakage paths, which can degrade device performance.

Additionally, amorphous high-k dielectric material is less etch resistant than crystalline high-k dielectric material. Portions of the high-k dielectric material can be removed during the subsequent etching processes of metal gate formation because of additional exposure of the portions to the etchants. For example, top portions of the high-k dielectric material in a FinFET can be removed during the etching processes and side portions of the high-k dielectric material in a nanostructure transistor can be removed during the etching processes. The nanostructure transistor can include the gate-all-around field effect transistor (GAA FET), the nanosheet transistor, the nanowire transistor, the multi-bridge channel transistor, the nano-ribbon transistor, and other similar structured transistors. The nanostructure transistor provides a channel in a stacked nanosheet/nanowire configuration. Nanostructure transistor devices are compatible with MOSFET manufacturing processes and their structure allows them to be scaled while maintaining gate control and mitigating short channel effects. The high-k dielectric material damage can cause electrical short, reduce gate control, and degrade device performance.

Furthermore, high-k dielectric material can be used in gate isolation structures to separate gate structures. The gate structures can extend across multiple active regions (e.g., fin regions) of the FinFET or nanostructure devices. Once the gate structures are formed, a patterning process can “cut” one or more of the gate structures into shorter sections according to the desired structure. In other words, the patterning process can remove gate portions of the one or more gate structures to form one or more isolation trenches (also referred to as “metal cuts”) between the devices and separate the gate structures into shorter sections. This process is referred to as a cut-metal-gate (CMG) process. Subsequently, the isolation trenches formed between the separated sections of the gate structures can be filled with the high-k dielectric material, such as hafnium oxide and zirconium oxide, to form gate isolation structures, which can electrically isolate the separated gate structure sections. The gate isolation structures filled with high-k dielectric material can also be referred to as “super CMG.” The gate isolation structures can include both amorphous and crystalline high-k dielectric material after formation. The leakage paths between the boundaries of amorphous and crystalline high-k dielectric material can cause electrical short between adjacent gate structure sections and thus degrade device performance.

Various embodiments in the present disclosure provide example methods for forming a crystalline high-k dielectric layer in a semiconductor device (e.g., a finFET or a nanostructure transistor) and/or other semiconductor devices in an integrated circuit (IC). In some embodiments, the semiconductor device can include a fin structure on a substrate, a gate dielectric layer on the fin structure, and a gate structure on the gate dielectric layer. A top portion of the gate dielectric layer can be crystalline and can include a crystalline high-k dielectric material. In some embodiments, the semiconductor device can include a nanostructure on a substrate, a gate dielectric layer wrapped around the nanostructure, and a gate structure wrapped around the gate dielectric layer. A sidewall portion of the gate dielectric layer can be crystalline and can include a crystalline high-k dielectric material. In some embodiments, a whole portion of the gate dielectric layer can be crystalline and can include a crystalline high-k dielectric material. In some embodiments, the semiconductor device can further include a gate isolation structure. The gate isolation structure can be crystalline and can include a crystalline high-k dielectric layer. In some embodiments, the crystalline high-k dielectric layer can be formed by a treatment in a hydrogen environment, such as hydrogen plasma, hydrogen radicals, and hydrogen gas. With the crystalline high-k dielectric layer, the gate dielectric layer and the gate isolation structure can have reduced leakage current and improved etch-resistance.

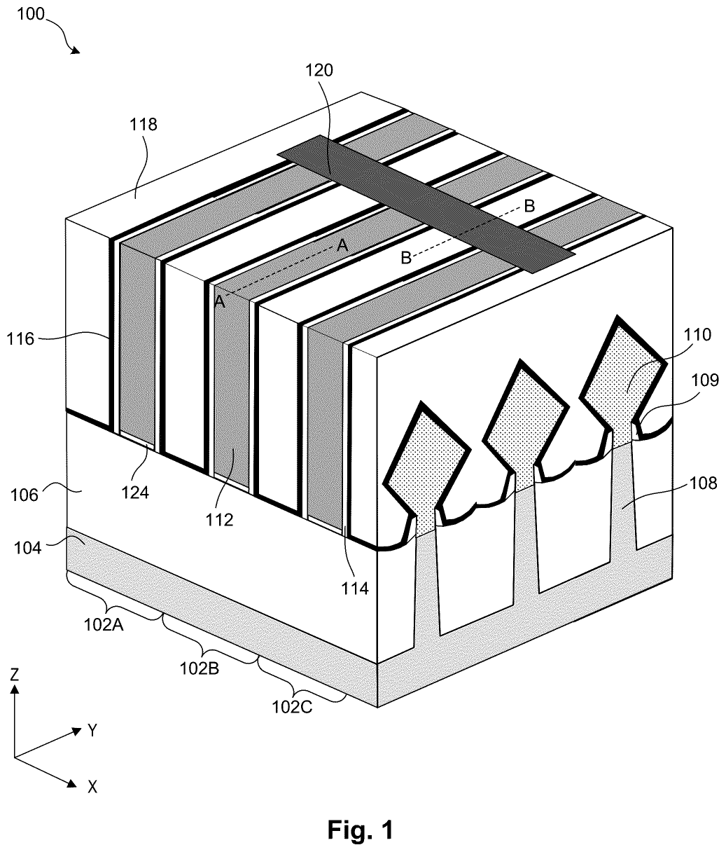

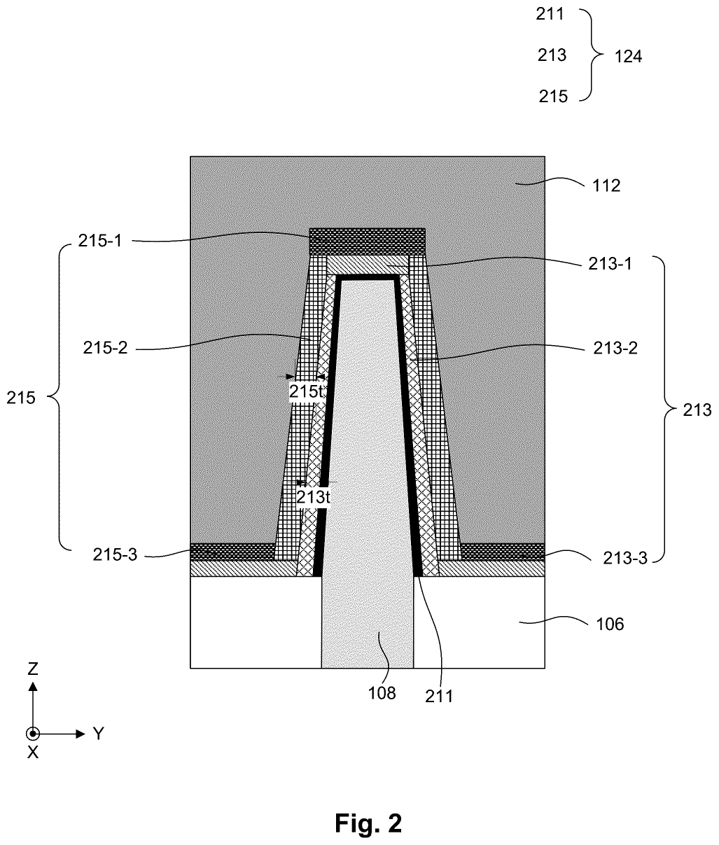

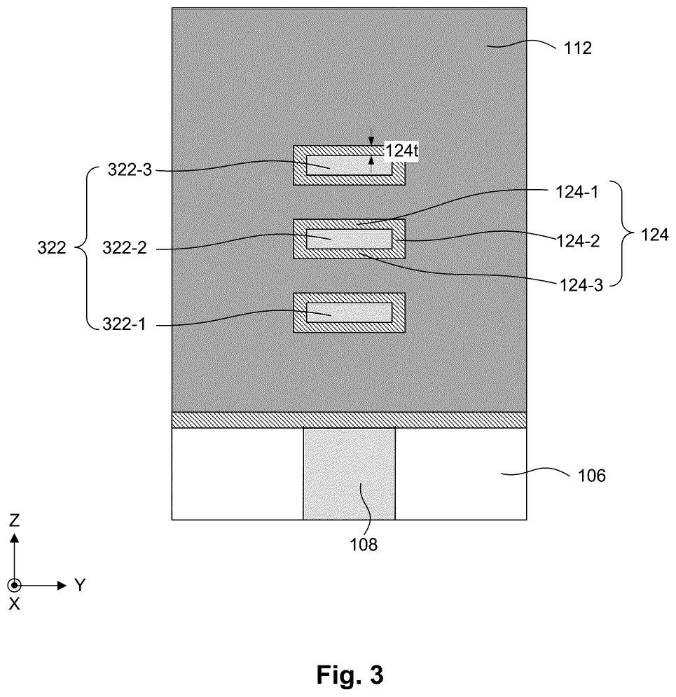

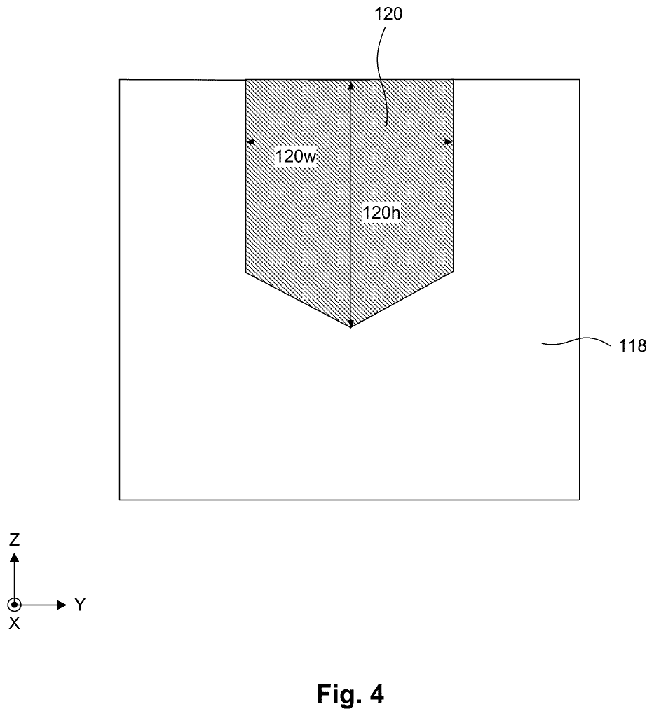

FIG. 1 illustrates an isometric view of a semiconductor device 100 having a crystalline high-k dielectric layer, in accordance with some embodiments. FIGS. 2 and 3 illustrate partial cross-sectional views of semiconductor device 100 across line A-A shown in FIG. 1, in accordance with some embodiments. FIG. 4 illustrates a partial cross-sectional view of semiconductor device 100 along line B-B shown in FIG. 1, in accordance with some embodiments.

In some embodiments, semiconductor device 100 can include finFETs 102A-102C, as shown in FIGS. 1 and 2. In some embodiments, semiconductor device 100 can include nanostructure transistors 102A-102C, as shown in FIGS. 1 and 3. In some embodiments, finFETs 102A-102C and nanostructure transistors 102A-102C can be both referred to as “transistors 102A-102C.” In some embodiments, transistors 102A-102C can be n-type field-effect transistors (NFETs). In some embodiments, transistors 102A-102C can be p-type nanostructure field-effect transistors (PFETs). In some embodiments, any of transistors 102A-102C can be an NFET or a PFET. Though FIG. 1 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1-4, semiconductor device 100 having transistors 102A-102C can be formed on a substrate 104 and can be isolated by shallow trench isolation (STI) regions 106. Each of transistors 102A-102C can include fin structures 108, fin sidewall spacers 109, gate dielectric layer 124, gate structures 112, gate spacers 114, S/D structures 110, etch stop layer (ESL) 116, interlayer dielectric (ILD) layer 118, and gate isolation structure 120. In some embodiments, as shown in FIG. 2, finFETs 102A-102C can have fin structures 108 extending above STI regions 106 under gate structures 112. In some embodiments, as shown in FIG. 3, nanostructure transistors 102A-102C can have nanostructures 322-1, 322-2, and 322-3 (collectively referred to as “nanostructures 322”) on fin structures 108.

Referring to FIG. 1, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102C and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1-4, nanostructures 322 and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1-3, nanostructures 322 and fin structures 108 can extend along an X-axis and through transistors 102A-102C. In some embodiments, nanostructures 322 and fin structures 108 can be disposed on substrate 104. Nanostructures 322 can include a set of nanostructures 322-1, 322-2, and 322-3, which can be in the form of nanosheets, nanowires, or nano-ribbons. Each of nanostructures 322 can form a channel region underlying gate structures 112 of transistors 102A-102C. In some embodiments, nanostructures 322 and fin structures 108 can include semiconductor materials similar to or different from substrate 104. In some embodiments, nanostructures 322 and fin structures 108 can include silicon. In some embodiments, nanostructures 322 and fin structures 108 can include silicon germanium. The semiconductor materials of nanostructures 322 and fin structures 108 can be undoped or can be in-situ doped during their formation process. In some embodiments, as shown in FIG. 2, fin structures 108 under gate structures 112 can form channel regions of semiconductor device 100 and represent current carrying structures of semiconductor device 100. In some embodiments, as shown in FIG. 3, nanostructures 322 under gate structures 112 can form channel regions of semiconductor device 100 and represent current carrying structures of semiconductor device 100. Though three layers of nanostructures 322 are shown in FIG. 3, transistors 102A-102C can have any number of nanostructures 322.

Referring to FIG. 2, gate dielectric layer 124 can be multi-layered structures and can be formed on fin structures 108 and STI regions 106. As shown in FIG. 2, gate dielectric layer 124 can include an interfacial layer 211, a first high-k dielectric layer 213, and a second high-k dielectric layer 215. In some embodiments, gate dielectric layer 124 can include first high-k dielectric layer 213 in direct contact with fin structures 108. In some embodiments, interfacial layer 211 can include silicon oxide formed by a deposition process or an oxidation process. In some embodiments, interfacial layer 211 can have a thickness ranging from about 0.1 nm to about 1.5 nm.

In some embodiments, first high-k dielectric layer 213 can include hafnium oxide, zirconium oxide, or other suitable high-k dielectric materials. In some embodiments, first high-k dielectric layer 213 can include a top portion 213-1 on a top surface of fin structures 108, a sidewall portion 213-2 on a sidewall surface of fin structures 108, and a bottom portion 213-3 on STI regions 106. In some embodiments, top portion 213-1 and bottom portion 213-3 of first high-k dielectric layer 213 can be crystalline and can have a crystalline high-k dielectric material. Sidewall portion 213-2 of first high-k dielectric layer 213 can be amorphous and can have an amorphous high-k dielectric material. In some embodiments, top portion 215-1 can have more exposure to etchants than sidewall portion 215-2 during etching processes of gate formation. Because the crystalline high-k dielectric material can be more etch-resistant than the amorphous high-k dielectric material, first high-k dielectric layer 213 can have reduced high-k damage with the crystalline high-k dielectric material at top portion 213-1 and bottom portion 213-3. In some embodiments, top portion 213-1 and sidewall portion 213-2 can be crystalline and can have the crystalline high-k dielectric material to reduce high-k damage. In some embodiments, top portion 213-1, sidewall portion 213-2, and bottom portion 213-3 can be crystalline and can have the crystalline high-k dielectric material to further reduce high-k damage. In some embodiments, first high-k dielectric layer 213 can have a thickness 213t less than about 5 nm. In some embodiments, thickness 213t of first high-k dielectric layer 213 can range from about 0.1 nm to about 5 nm. If thickness 213t is greater than about 5 nm, portions of first high-k dielectric layer 213, such as top portion 213-1, sidewall portion 213-2, and bottom portion 213-3, may have a partially crystalline high-k dielectric material mixed with an amorphous high-k dielectric material. If thickness 213t is less than about 0.1 nm, first high-k dielectric layer 213 may not be uniform.

In some embodiments, second high-k dielectric layer 215 can be disposed on first high-k dielectric layer 213 and can include hafnium oxide, zirconium oxide, or other suitable high-k dielectric materials. In some embodiments, second high-k dielectric layer 215 can include a high-k dielectric material different from first high-k dielectric layer 213. In some embodiments, second high-k dielectric layer 215 can include zirconium oxide, and first high-k dielectric layer 213 can include hafnium oxide. In some embodiments, second high-k dielectric layer 215 can have a higher dielectric constant than first high-k dielectric layer 213. In some embodiments, second high-k dielectric layer 215 can be less etch-resistant than first high-k dielectric layer 213. In some embodiments, second high-k dielectric layer 215 can have a thickness 215t ranging from about 0.1 nm to about 1 nm. In some embodiments, a ratio of thickness 213t to thickness 215t can range from about 5 to about 15. If thickness 215t is greater than about 1 nm, or the ratio is less than about 5, gate dielectric layer 124 may be less etch-resistant and may have additional high-k damage during the etching processes of gate formation. If thickness 215t is less than about 0.1 nm, or the ratio is greater than about 15, second high-k dielectric layer 215 may not be uniform.

In some embodiments, similar to first high-k dielectric layer 213, second high-k dielectric layer 215 can include a top portion 215-1, a sidewall portion 215-2, and a bottom portion 215-3. In some embodiments, top portion 215-1 and bottom portion 215-3 of second high-k dielectric layer 215 can be crystalline and can have a crystalline high-k dielectric material. Sidewall portion 215-2 of second high-k dielectric layer 215 can be amorphous and can have an amorphous high-k dielectric material. In some embodiments, top portion 215-1 can have more exposure to etchants than sidewall portion 215-2 during subsequent etching processes. Because the crystalline high-k dielectric material can be more etch-resistant than the amorphous high-k dielectric material, second high-k dielectric layer 215 can have reduced high-k damage with the crystalline high-k dielectric material at top portion 215-1 and bottom portion 215-3. In some embodiments, top portion 215-1 and sidewall portion 215-2 can be crystalline and can have the crystalline high-k dielectric material to reduce high-k damage. In some embodiments, top portion 215-1, sidewall portion 215-2, and bottom portion 215-3 can be crystalline and can have the crystalline high-k dielectric material to further reduce high-k damage. In some embodiments, first high-k dielectric layer 213 can be amorphous and can have an amorphous high-k dielectric material and second high-k dielectric layer 215 can have at least a crystalline top portion 215-1 with a crystalline high-k dielectric material. Because top portion 215-1 of second high-k dielectric layer 215 can have more exposure to etchants than other portions of first and second high-k dielectric layers 213 and 215 during subsequent etching processes, first and second high-k dielectric layers 213 and 215 can have reduced high-k damage.

Referring to FIG. 3, gate dielectric layer 124 can be multi-layered structures as described in FIG. 2. Gate dielectric layer 124 can be formed on fin structures 108 and STI regions 106 and can wrap around nanostructures 322. In some embodiments, gate dielectric layer 124 in FIG. 3 can include interfacial layer 211, first high-k dielectric layer 213, and second high-k dielectric layer 215 as shown in FIG. 2. In some embodiments, gate dielectric layer 124 can include a top portion 124-1, a sidewall portion 124-2, and a bottom portion 124-3. In some embodiments, top portion 124-1, sidewall portion 124-2, and bottom portion 124-3 of gate dielectric layer 124 can be crystalline and can include a crystalline high-k dielectric material. Because the crystalline high-k dielectric material can be more etch-resistant than the amorphous high-k dielectric material and partially crystalline high-k dielectric material, the crystalline high-k dielectric material in gate dielectric layer 124 can reduce high-k material damage during subsequent etching processes. In some embodiments, sidewall portion 124-2 can have more exposure to etchants than sidewall portion 215-2 during subsequent etching processes. In some embodiments, sidewall portion 124-2 can be crystalline and can include a crystalline high-k dielectric material while top portion 124-1 and bottom portion 124-3 can be amorphous and can include an amorphous high-k dielectric material. The crystalline high-k dielectric material in sidewall portion 124-2 of gate dielectric layer 124 can reduce high-k material damage during subsequent etching processes. In some embodiments, gate dielectric layer 124 can have a thickness 124t ranging from about 0.1 nm to about 5 nm. If thickness 124t is greater than about 5 nm, gate dielectric layer 124 may have partially crystalline high-k dielectric material mixed with amorphous high-k dielectric material, which can have lower etch-resistance and higher leakage currents. If thickness 124t is less than about 0.1 nm, deposited gate dielectric layer 124 may not be uniform.

S/D structures 110 can be disposed on substrate 104 and on opposing sides of gate structures 112. S/D structures 110 can function as S/D regions of transistors 102A-102C. In some embodiments, S/D structures 110 can have any geometric shape, such as a polygon, an ellipsis, and a circle. In some embodiments, S/D structures 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium, and imparts a strain on the channel regions under gate structures 112. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 110 can include one or more epitaxial layers, where each epitaxial layer can have different compositions.

In some embodiments, as shown in FIG. 2, gate structures 112 can be disposed on gate dielectric layer 124. In some embodiments, gate structure 112 can include one or more work function metal layers and a metal fill. The one or more work function metal layers can include work function metals to tune the threshold voltage (Vₜ) of transistors 102A-102C. In some embodiments, as shown in FIG. 3, each of nanostructures 322 can be wrapped around by gate structures 112, in which gate structures 112 can be referred to as “gate-all-around (GAA) structures” and transistors 102A-102C can also be referred to as “GAA FETs 102A-102C.” The one or more work function metal layers can wrap around nanostructures 322 and can include work function metals to tune the Vₜ of transistors 102A-102C. In some embodiments, transistors 102A-102C can include any number of work function metal layers for Vₜ tuning (e.g., ultra-low Vₜ, low Vₜ, and standard Vₜ).

In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIG. 1, gate spacers 114 can be disposed on sidewalls of gate structures 112, and fin sidewall spacers 109 can be disposed on sidewalls of fin structures 108. Gate spacers 114 and fin sidewall spacers 109 can include insulating materials, such as silicon oxide, silicon nitride, silicon oxynitride, silicon carbonitride, silicon oxycarbide, silicon oxycarbonitride, a low-k material, and a combination thereof. Gate spacers 114 and fin sidewall spacers 109 can include a single layer or a stack of insulating layers. Gate spacers 114 and fin sidewall spacers 109 can have a low-k material with a dielectric constant less than about 3.9 (e.g., about 3.5, about 3.0, or about 2.8).

ESL 116 can be disposed on STI regions 106, S/D structures 110, and sidewalls of gate spacers 114 and fin sidewall spacers 109. ESL 116 can be configured to protect STI regions 106, S/D structures 110, and gate structures 112 during the formation of S/D contact structures on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

Gate isolation structure 120 can be disposed in gate structures 112 and ILD layer 118 to separate gate structures 112 into shorter portions, as shown in FIG. 1. Gate isolation structure 120 can extend vertically (e.g., along a Z-axis) through gate structures 112 to electrically isolate gate structures 112 between adjacent portions. In some embodiments, gate isolation structure 120 can include a single dielectric layer or a stack of dielectric layers. In some embodiments, gate isolation structure 120 can be crystalline and can include a crystalline high-k dielectric material. In some embodiments, the crystalline high-k dielectric material can include hafnium oxide, zirconium oxide, or other suitable high-k dielectric materials. In some embodiments, the high-k dielectric material in gate isolation structure 120 can be fully crystallized to improve etch-resistance during subsequent etching processes and reduce current leakage between adjacent portions of gate structures 112. In some embodiments, as shown in FIG. 4, gate isolation structure 120 can have a width 120w along a Y-axis ranging from about 5 nm to about 50 nm. If width 120w is less than about 5 nm, gate isolation structure 120 may not be able to isolate adjacent portions of gate structure 112. If width 120w is greater than about 50 nm, manufacturing cost may increase. In some embodiments, gate isolation structure 120 can have a height 120h along a Z-axis ranging from about 50 nm to about 200 nm. If height 120h is less than about 50 nm, gate isolation structure 120 may not fully isolate adjacent portions of gate structures 112. If height 120h is greater than about 200 nm, manufacturing cost may increase.

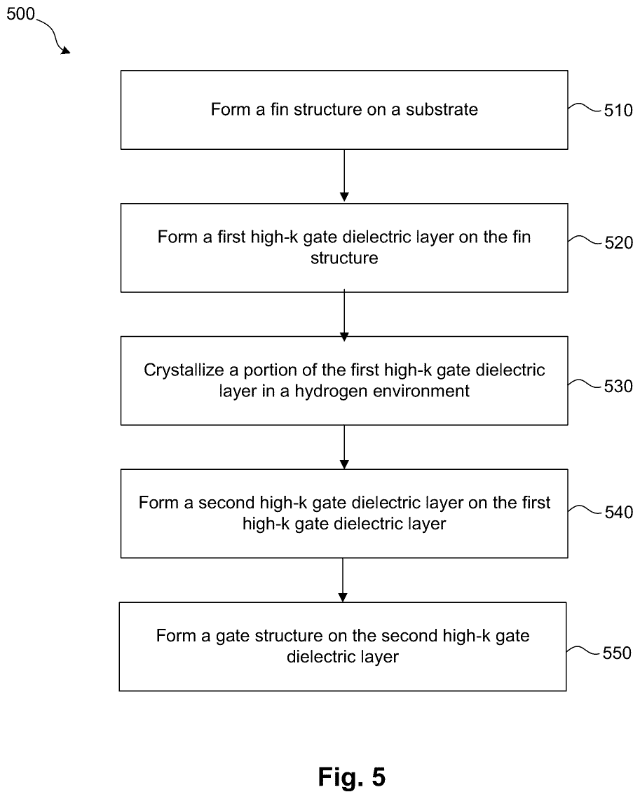

FIG. 5 is a flow diagram of a method 500 for fabricating semiconductor device 100 having a crystalline high-k dielectric layer, in accordance with some embodiments. Method 500 may not be limited to finFET or nanostructure transistor devices and can be applicable to other devices that would benefit from the crystalline high-k dielectric layer. Additional fabrication operations may be performed between various operations of method 500 and may be omitted merely for clarity and ease of description. Additional processes can be provided before, during, and/or after method 500; one or more of these additional processes are briefly described herein. Moreover, not all operations may be needed to perform the disclosure provided herein. Additionally, some of the operations may be performed simultaneously or in a different order than shown in FIG. 5. In some embodiments, one or more other operations may be performed in addition to or in place of the presently-described operations.

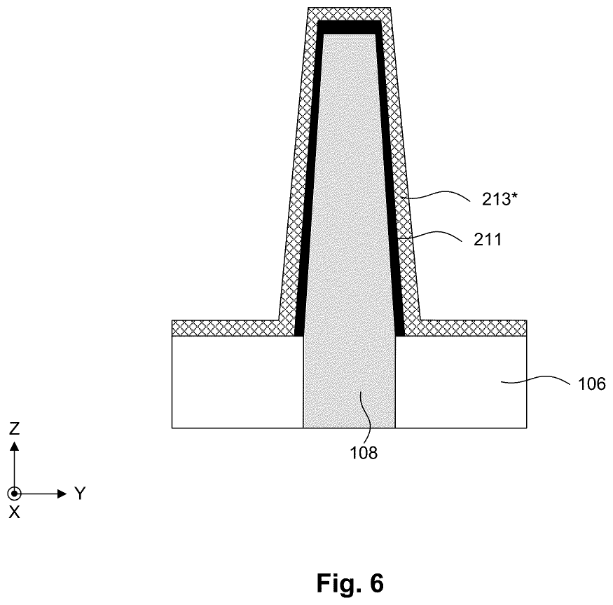

For illustrative purposes, the operations illustrated in FIG. 5 will be described with reference to the example fabrication process for fabricating semiconductor device 100 as illustrated in FIGS. 6-21. FIGS. 6-21 illustrate partial cross-sectional views of semiconductor device 100 having a crystalline high-k gate dielectric layer at various stages of its fabrication, in accordance with some embodiments. Elements in FIGS. 6-21 with the same annotations as elements in FIGS. 1-4 are described above.

In referring to FIG. 5, method 500 begins with operation 510 and the process of forming a fin structure on a substrate. For example, as shown in FIGS. 1 and 6, fin structures 108 can be formed on substrate 104. FIG. 6 illustrates a partial cross-sectional view of semiconductor device 100 along line A-A as shown in FIG. 1, in accordance with some embodiments. In some embodiments, fin structures 108 can extend above STI regions 106. In some embodiments, fin structures 108 can include silicon. In some embodiments, fin structures 108 can include silicon germanium. The semiconductor materials of fin structures 108 can be undoped or can be in-situ doped during their formation process. In some embodiments, following the formation of fin structures 108, interfacial layer 211 can be formed on fin structures 108, as shown in FIGS. 1 and 6. In some embodiments, interfacial layer 211 can include silicon oxide formed by a deposition process or an oxidation process. In some embodiments, interfacial layer 211 can have a thickness ranging from about 0.1 nm to about 1.5 nm.

Referring to FIG. 5, in operation 520, a first high-k gate dielectric layer is formed on the fin structure. For example, as shown in FIG. 6, first high-k dielectric layer 213* can be formed on fin structures 108. In some embodiments, first high-k dielectric layer 213* can be deposited on interfacial layer 211 and STI regions 106. In some embodiments, first high-k dielectric layer 213* can be deposited on fin structures 108 and STI regions 106. First high-k dielectric layer 213* can be conformally deposited at a temperature from about 200° C. to about 400° C. by atomic layer deposition (ALD), chemical vapor deposition (CVD), or other suitable deposition methods. In some embodiments, first high-k dielectric layer 213* can be amorphous after deposition. In some embodiments, deposited first high-k dielectric layer 213* needs to be fully amorphous to achieve uniform crystallization in the subsequent crystallization treatment. In some embodiments, first high-k dielectric layer 213* can include hafnium oxide, zirconium oxide, or other suitable high-k dielectric materials. In some embodiments, first high-k dielectric layer 213* can have thickness 213t less than about 5 nm to keep the deposited high-k dielectric material amorphous. In some embodiments, thickness 213t of first high-k dielectric layer 213* can range from about 0.1 nm to about 5 nm to keep deposited first high-k dielectric layer 213* amorphous. If thickness 213t is greater than about 5 nm, first high-k dielectric layer 213* may have partially amorphous high-k dielectric material mixed with crystalline high-k dielectric material, which can have a higher leakage current and a lower etch-resistance. If thickness 213t is less than about 0.1 nm, deposited first high-k dielectric layer 213* may not be uniform.

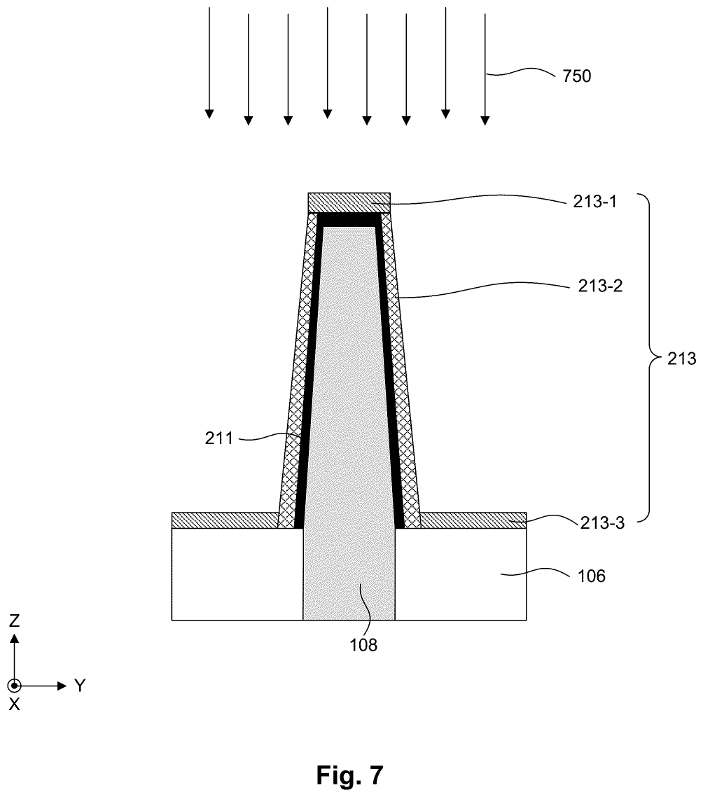

Referring to FIG. 5, in operation 530, a portion of the first high-k gate dielectric layer is crystallized in a hydrogen environment. For example, as shown in FIG. 7, top portion 213-1 and bottom portion 213-3 of first high-k dielectric layer 213* can be crystallized by hydrogen plasma 750. In some embodiments, hydrogen plasma 750 can be directional and can crystallize top portion 213-1 and bottom portion 213-3 but not sidewall portion 213-2. In some embodiments, crystallization of high-k dielectric layer 213* can improve its etch resistance by about 20 to about 30 times.

In some embodiments, hydrogen plasma 750 can be formed by a mixture of nitrogen gas and hydrogen gas at a power from about 10 W to about 100 W under a pressure from about 1 torr to about 100 torr. In some embodiments, a hydrogen concentration in the plasma can range from about 0.05% to about 1%. In some embodiments, first high-k dielectric layer 213* can be treated with hydrogen plasma 750 at a temperature from about 450° C. to about 650° C. for a time period from about 10 s to about 200 s. If the power is less than about 10 W, the pressure is less than about 1 torr, the hydrogen concentration is less than about 0.05%, or the temperature is less than about 450° C., top portion 213-1 and bottom portion 213-3 may not be fully crystallized. If the power is greater than about 100 W, the pressure is greater than about 100 torr, the hydrogen concentration is greater than about 1%, or the temperature is greater than about 650° C., gate dielectric layer 124 may be damaged.

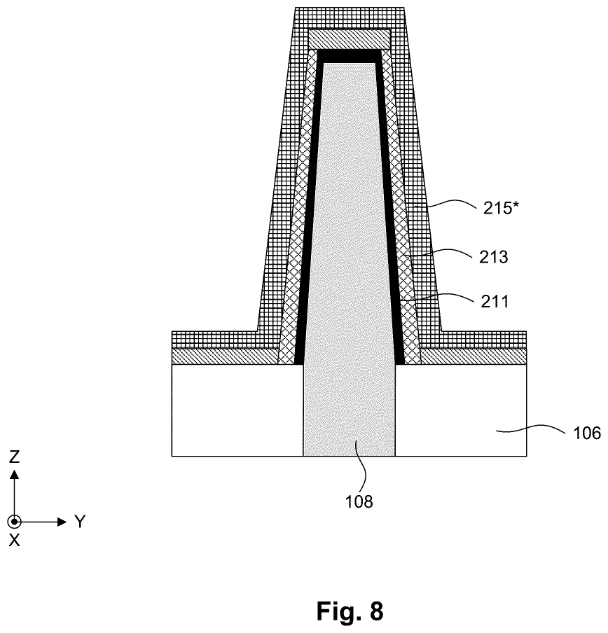

Referring to FIG. 5, in operation 540, a second high-k date dielectric layer is formed on the first high-k gate dielectric layer. For example, as shown in FIG. 8, second high-k dielectric layer 215* can be formed on first high-k dielectric layer 213. In some embodiments, similar to first high-k dielectric layer 213*, second high-k dielectric layer 215* can be conformally deposited at a temperature from about 200° C. to about 400° C. by ALD, CVD, or other suitable deposition methods. In some embodiments, second high-k dielectric layer 215* can be amorphous after deposition. In some embodiments, deposited second high-k dielectric layer 215* needs to be fully amorphous to achieve uniform crystallization in the subsequent crystallization treatment. In some embodiments, second high-k dielectric layer 215* can include hafnium oxide, zirconium oxide, or other suitable high-k dielectric materials. In some embodiments, second high-k dielectric layer 215* can include a high-k dielectric material different from first high-k dielectric layer 213*. In some embodiments, second high-k dielectric layer 215* can include zirconium oxide, and first high-k dielectric layer 213* can include hafnium oxide. In some embodiments, second high-k dielectric layer 215* can be less etch-resistant than first high-k dielectric layer 213*. In some embodiments, second high-k dielectric layer 215* can have thickness 215t less than thickness 213t of first high-k dielectric layer 213*. In some embodiments, thickness 215t ranges from about 0.1 nm to about 1 nm. In some embodiments, a ratio of thickness 213t to thickness 215t can range from about 15 to about 5. If thickness 215t is greater than about 1 nm, or the ratio is less than about 5, gate dielectric layer 124 may be less etch-resistant and may have additional high-k damage during subsequent etching processes. If thickness 215t is less than about 0.1 nm, or the ratio is greater than about 15, second high-k dielectric layer 215 may not be uniform.

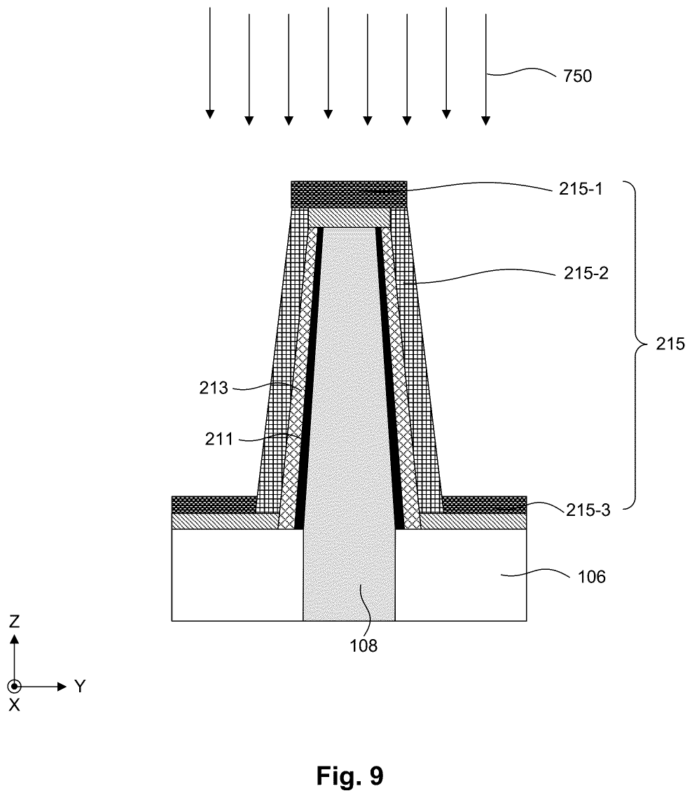

In some embodiments, the formation of second high-k dielectric layer 215* can be followed by crystallization of a portion of second high-k dielectric layer 215*. For example, as shown in FIG. 9, top portion 215-1 and bottom portion 215-3 of second high-k dielectric layer 215* can be crystallized by hydrogen plasma 750, similar to first high-k dielectric layer 213. In some embodiments, hydrogen plasma 750 can be directional and can crystallize top portion 215-1 and bottom portion 215-3 but not sidewall portion 215-2. In some embodiments, crystallization of second high-k dielectric layer 215* can improve its etch resistance by about 5 to about 30 times. In some embodiments, hydrogen plasma 750 can be formed at a similar condition as described in operation 530. In some embodiments, first high-k dielectric layer 213* can be formed on fin structure 108 and second high-k dielectric layer 215* can be formed on first high-k dielectric layer 213*. Top portions 213-1 and 215-1 and bottom portions 213-3 and 215-3 can be crystallized by hydrogen plasma 750 in one operation of hydrogen plasma treatment. In some embodiments, one operation of hydrogen plasma treatment can crystalize more than two high-k dielectric layers.

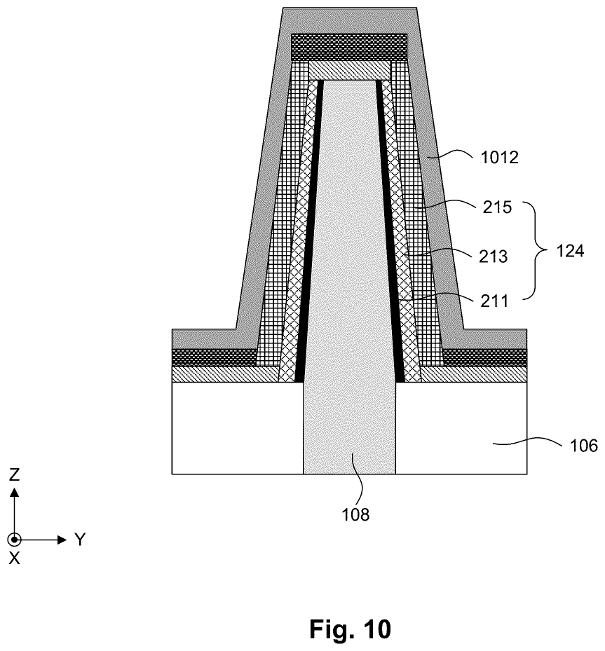

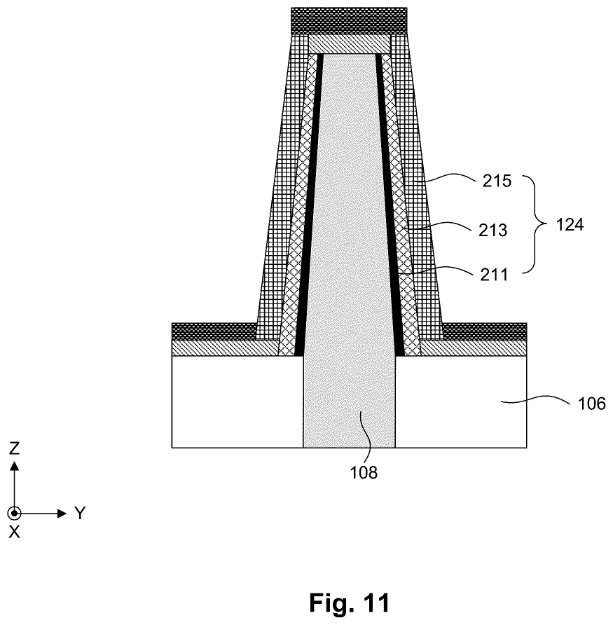

Referring to FIG. 5, in operation 550, a gate structure is formed on second high-k gate dielectric layer. For example, as shown in FIGS. 2, 10, and 11, gate structures 112 can be formed on second high-k dielectric layer 215. In some embodiments, the formation of gate structures 112 can include formation of a stack of work function metal layers and formation of a metal fill. In some embodiments, the formation of the work function metal layers can include multiple operations of deposition and removal of work function metal layers to form n-type and p-type transistors with multiple threshold voltages (Vₜ), such as, ultra-low Vₜ, low Vₜ, and standard Vₜ. For example, as shown in FIG. 10, work function layer 1012 can be deposited on second high-k dielectric layer 215 by ALD, CVD, physical vapor deposition (PVD), e-beam deposition, or other suitable deposition methods. In some embodiments, as shown in FIG. 11, work function layer 1012 can be removed in subsequent etching processes to form transistors with a certain Vₜ. In some embodiments, the subsequent etching processes can remove amorphous high-k dielectric materials but may not remove crystalline high-k dielectric materials. Additionally, top portions 213-1 and 215-1 can have more exposure to the etchants of the subsequent etching processes. With crystallized top portions 213-1 and 215-1 of first and second high-k dielectric layers 213 and 215, gate dielectric layer 124 can have less high-k damage, and gate dielectric layer 124 can better protect fin structures 108. After the formation of additional work function layers and the metal fill, gate structures 112 can be formed on second high-k dielectric layer 215 over fin structures 108, as shown in FIG. 2.

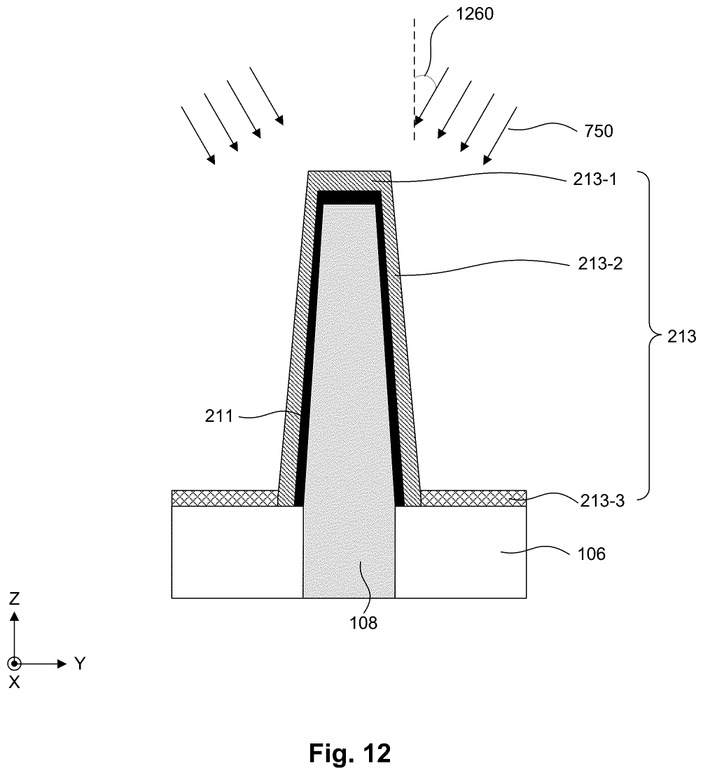

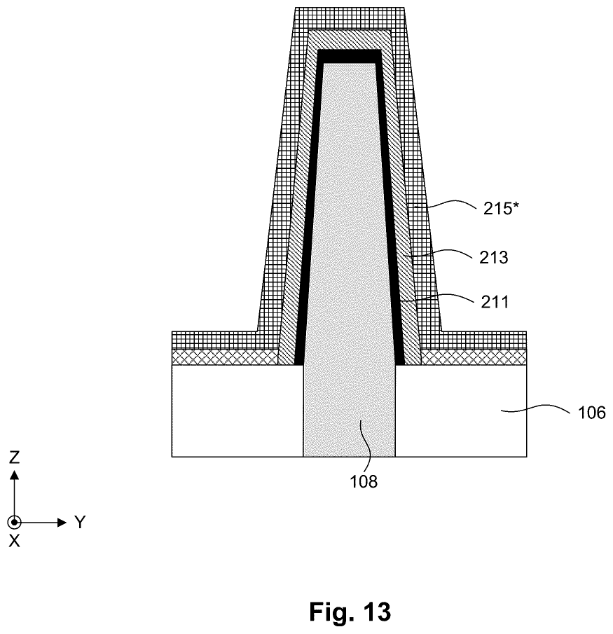

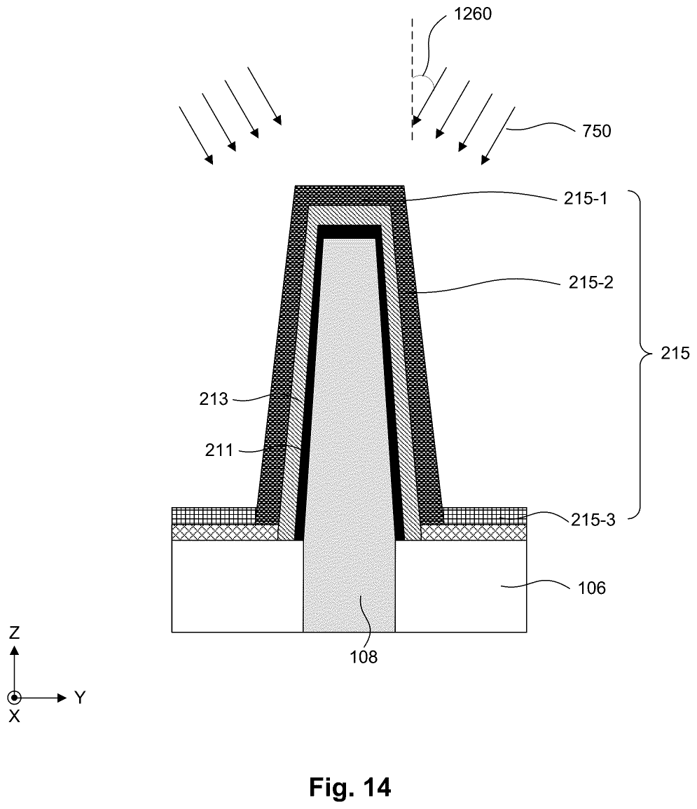

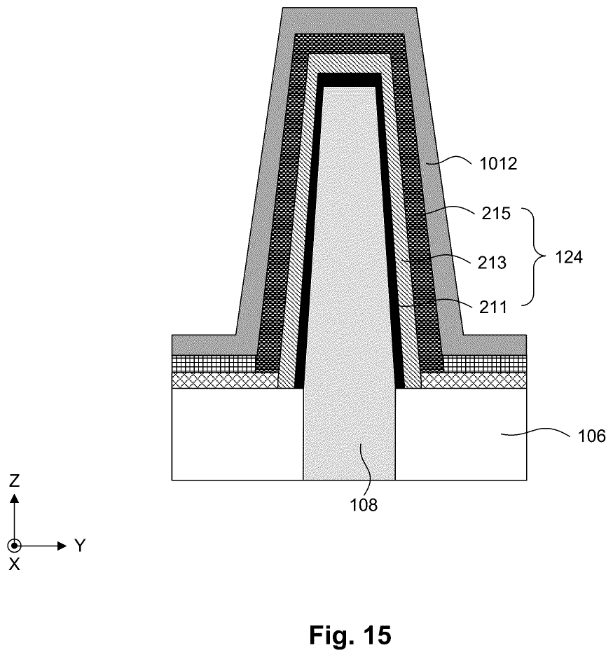

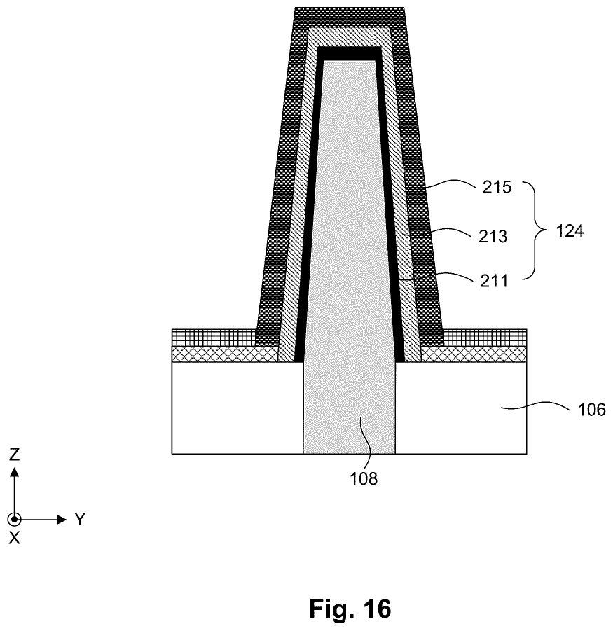

In some embodiments, the hydrogen treatment can be performed with a tilted hydrogen plasma 750, as shown in FIG. 12. In some embodiments, hydrogen plasma 750 can be tilted at an angle 1260 ranging from about 0 degree to about 60 degree. Tilted hydrogen plasma 750 can be directional and can crystallize top portion 213-1 and sidewall portion 213-2 but not bottom portion 213-3, as shown in FIG. 12. In some embodiments, second high-k dielectric layer 215* can be conformally deposited on first high-k dielectric layer 213 and crystallized by tilted hydrogen plasma 750, as shown in FIGS. 13 and 14. Similar to first high-k dielectric layer 213, tilted hydrogen plasma 750 can be directional and can crystallize top portion 215-1 and sidewall portion 215-2 but not bottom portion 215-3 of second high-k dielectric layer 215. After deposition and removal of work function metal layer 1512, first and second high-k dielectric layers 213 and 215 may not be damaged because of crystallized top portions 213-1 and 215-1 as well as crystallized sidewall portions 213-2 and 215-2, as shown in FIGS. 15 and 16.

In some embodiments, the hydrogen treatment can be performed by an anneal process with hydrogen radicals or hydrogen gases. In some embodiments, after first high-k dielectric layer 213 is conformally deposited, the anneal process can be performed at a temperature from about 450° C. to about 650° C. under a pressure from about 1 torr to about 100 torr for a time period from about 10 s to about 200 s. In some embodiments, the hydrogen radicals and hydrogen gas can include a mixture of nitrogen gases and hydrogen gases. In some embodiments, a concentration of the hydrogen gases in the gas mixture can range from about 5% to about 100%. If the pressure is less than about 1 torr, the hydrogen concentration is less than about 5%, or the temperature is less than about 450° C., first high-k dielectric layer 213 may not be fully crystallized. If the pressure is greater than about 100 torr or the temperature is greater than about 650° C., first high-k dielectric layer 213 may be damaged.

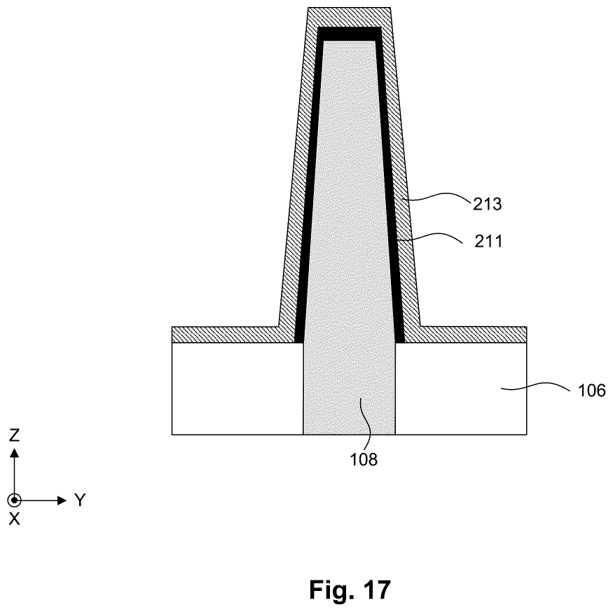

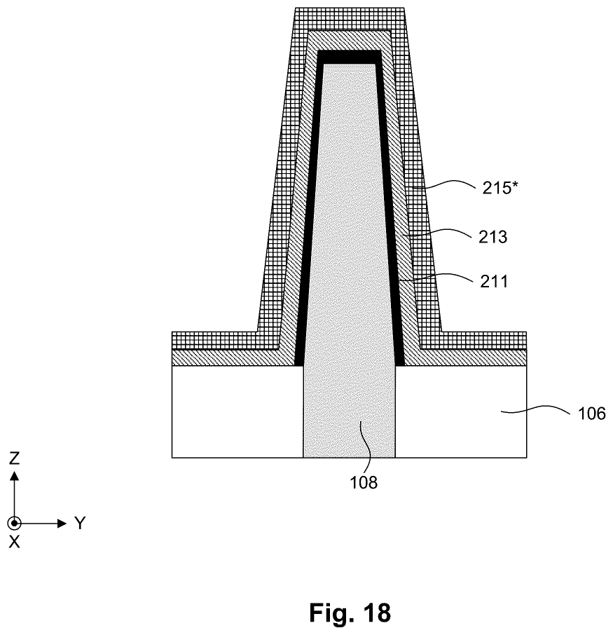

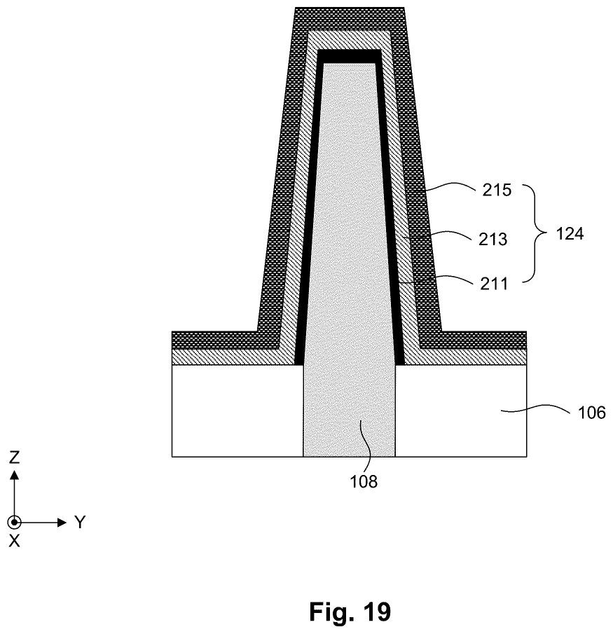

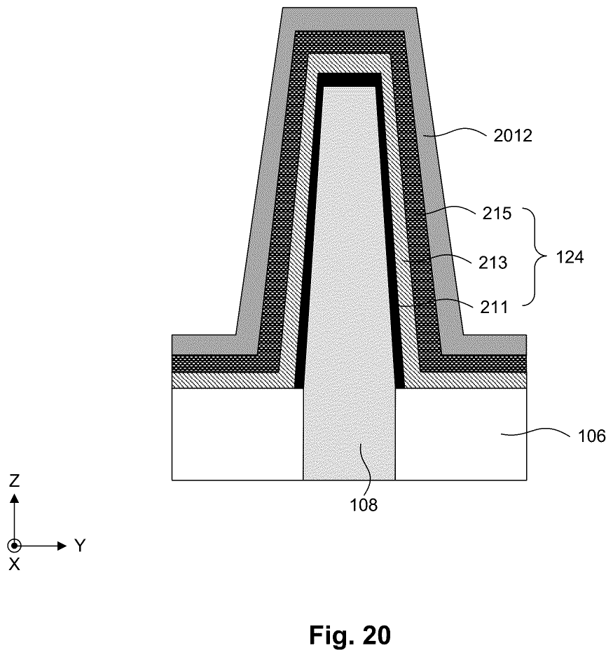

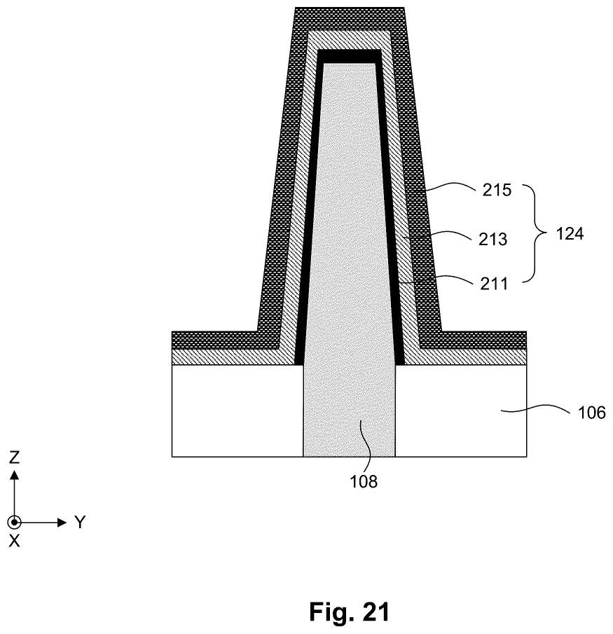

In some embodiments, after the anneal process with hydrogen radicals or hydrogen gases, top, sidewall, and bottom portions of first high-k dielectric layer 213 can be fully crystallized, as shown in FIG. 17. In some embodiments, second high-k dielectric layer 215* can be conformally deposited on first high-k dielectric layer 213 and crystallized by an anneal process with hydrogen radicals or hydrogen gases, as shown in FIGS. 18 and 19. Similar to first high-k dielectric layer 213, hydrogen radicals and hydrogen gases can fully crystallize top, sidewall, and bottom portions of second high-k dielectric layer 215. After deposition and removal of work function metal layer 2012, first and second high-k dielectric layers 213 and 215 may not be damaged because of the fully crystallized top, sidewall, and bottom portions, as shown in FIGS. 20 and 21.

In some embodiments, to prevent high-k damage and reduce leakage current, different portions of first and second high-k dielectric layer 213 and 215 can be crystallized by directional hydrogen plasma 750, tilted hydrogen plasma 750, or annealed in hydrogen radicals or hydrogen gases. In some embodiments, top and bottom portions of first high-k dielectric layer 213 can be crystallized by directional hydrogen plasma 750, and top and sidewall portions of second high-k dielectric layer 215 can be crystallized by titled hydrogen plasma 750. In some embodiments, top and bottom portions of first high-k dielectric layer 213 can be crystallized by directional hydrogen plasma 750, and top, sidewall, and bottom portions of second high-k dielectric layer 215 can be crystallized by an anneal process in hydrogen radicals or hydrogen gases. In some embodiments, top and sidewall portions of first high-k dielectric layer 213 can be crystallized by tilted hydrogen plasma 750, and top and bottom portions of second high-k dielectric layer 215 can be crystallized by directional hydrogen plasma 750. In some embodiments, top and sidewall portions of first high-k dielectric layer 213 can be crystallized by tilted hydrogen plasma 750, and top, sidewall, and bottom portions of second high-k dielectric layer 215 can be crystallized by an anneal process in hydrogen radicals or hydrogen gases. In some embodiments, top, sidewall, and bottom portions of first high-k dielectric layer 213 can be crystallized by an anneal process in hydrogen radicals or hydrogen gases, and top and sidewall portions of second high-k dielectric layer 213 can be crystallized by tilted hydrogen plasma 750. In some embodiments, top, sidewall, and bottom portions of first high-k dielectric layer 213 can be crystallized by an anneal process in hydrogen radicals or hydrogen gases and top and bottom portions of second high-k dielectric layer 215 can be crystallized by directional hydrogen plasma 750.

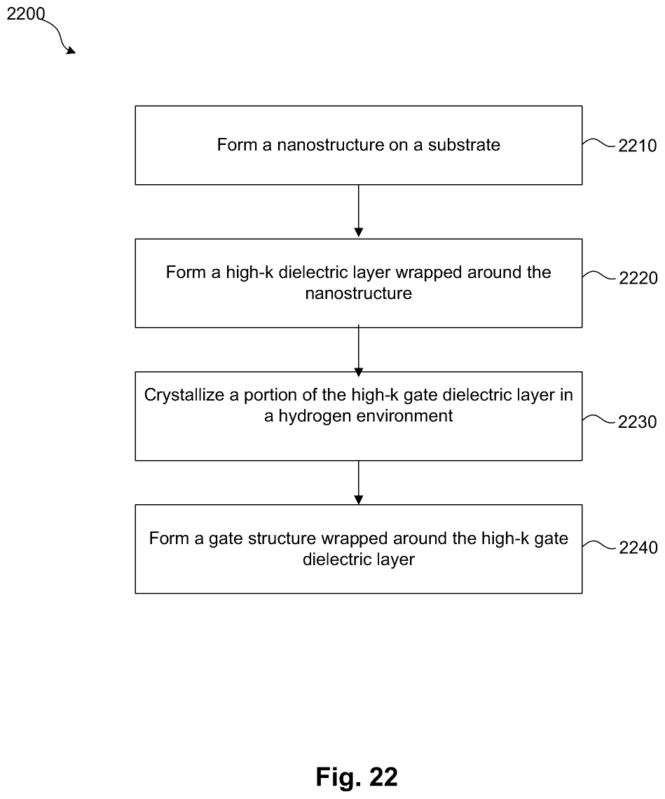

FIG. 22 is a flow diagram of a method 2200 for fabricating semiconductor device 100 having a crystalline high-k dielectric layer, in accordance with some embodiments. Method 2200 may not be limited to finFET or nanostructure transistor devices and can be applicable to other devices that would benefit from the crystalline high-k dielectric layer. Additional fabrication operations may be performed between various operations of method 2200 and may be omitted merely for clarity and ease of description. Additional processes can be provided before, during, and/or after method 2200; one or more of these additional processes are briefly described herein. Moreover, not all operations may be needed to perform the disclosure provided herein. Additionally, some of the operations may be performed simultaneously or in a different order than shown in FIG. 22. In some embodiments, one or more other operations may be performed in addition to or in place of the presently-described operations.

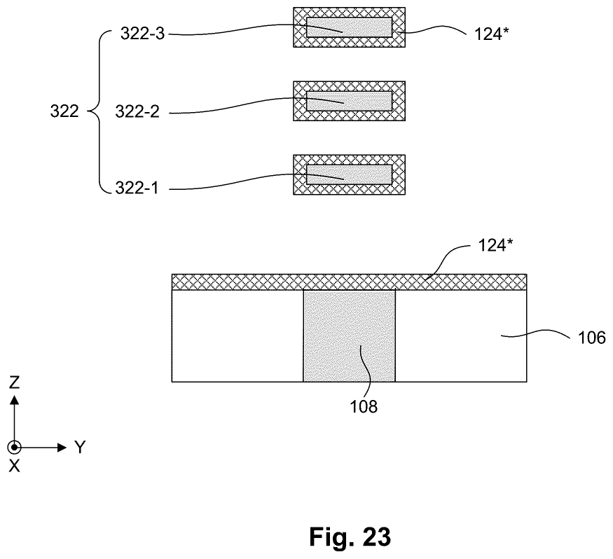

For illustrative purposes, the operations illustrated in FIG. 22 will be described with reference to the example fabrication process for fabricating semiconductor device 100 as illustrated in FIGS. 23-29. FIGS. 23-29 illustrate partial cross-sectional views of semiconductor device 100 having a crystalline high-k gate dielectric layer at various stages of its fabrication, in accordance with some embodiments. Elements in FIGS. 23-29 with the same annotations as elements in FIGS. 1-21 are described above.

In referring to FIG. 22, method 2200 begins with operation 2210 and the process of forming a nanostructure on a substrate. For example, as shown in FIG. 23, nanostructures 322-1, 322-2, and 322-3 can be formed on substrate 104. FIG. 23 illustrates a partial cross-sectional view of semiconductor device 100 along line A-A as shown in FIG. 1, in accordance with some embodiments. In some embodiments, nanostructures 322 can be epitaxially grown on substrate 104 and stacked with additional nanostructures in an alternate configuration. Nanostructures 322 and the additional nanostructures can be patterned by double- or multi-patterning processes described above. The additional nanostructures can be removed in subsequent processes to form nanostructures 322 stacked vertically and separated from each other, as shown in FIG. 23. In some embodiments, nanostructures 322 can be in the form of nanosheets, nanowires, or nano-ribbons. In some embodiments, nanostructures 322 and fin structures 108 can include semiconductor materials similar to or different from substrate 104.

Referring to FIG. 22, in operation 2220, a high-k gate dielectric layer is formed around the nanostructure. For example, as shown in FIG. 23, gate dielectric layer 124* can be formed wrapping around nanostructures 322 and on fin structures 108 and STI regions 106. In some embodiments, gate dielectric layer 124* can include interfacial layer 211, first high-k dielectric layer 213, and second high-k dielectric layer 215 as shown in FIGS. 2 and 3. In some embodiments, gate dielectric layer 124* can be conformally deposited on nanostructures 322 at a temperature from about 200° C. to about 400° C. by ALD, CVD, or other suitable deposition methods. In some embodiments, gate dielectric layer 124* can be amorphous after deposition. In some embodiments, gate dielectric layer 124* needs to be fully amorphous to achieve uniform crystallization in the subsequent crystallization treatment. In some embodiments, gate dielectric layer 124* can include hafnium oxide, zirconium oxide, or other suitable high-k dielectric materials. In some embodiments, gate dielectric layer 124* can have thickness 124t ranging from about 0.1 nm to about 5 nm. If thickness 124t is greater than about 5 nm, gate dielectric layer 124* may have partially amorphous high-k dielectric material mixed with crystalline high-k dielectric material, which can have lower etch-resistance and higher leakage currents. If thickness 124t is less than about 0.1 nm, deposited gate dielectric layer 124* may not be uniform.

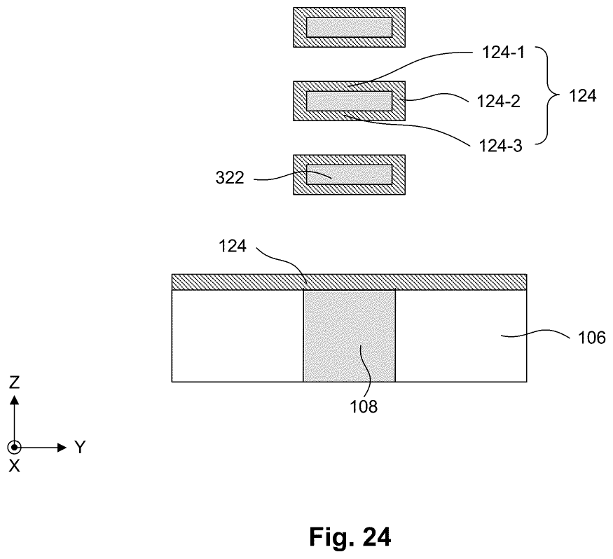

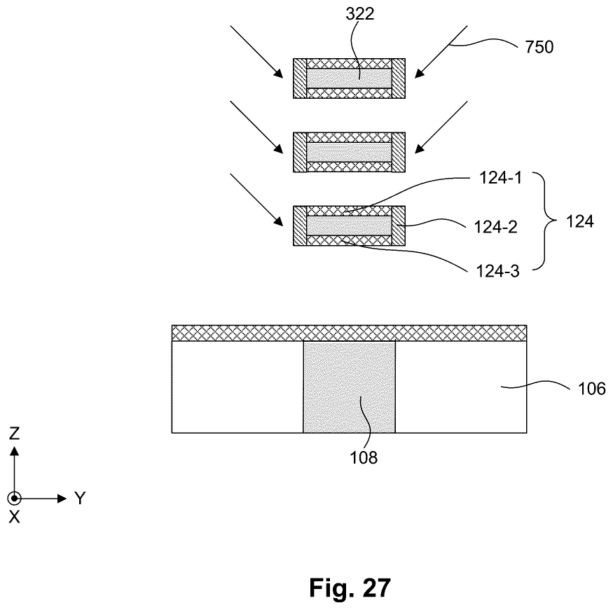

Referring to FIG. 22, in operation 2230, a portion of the high-k gate dielectric layer is crystallized in a hydrogen environment. For example, as shown in FIG. 24, top portion 124-1, sidewall portion 124-2, and bottom portion 124-3 of gate dielectric layer 124 can be crystallized by an anneal process with hydrogen radicals or hydrogen gases, as described in detail in FIGS. 17-21. In some embodiments, as shown in FIGS. 27-29, sidewall portion 124-2 can be crystallized by tilted hydrogen plasma 750, as described in detail in FIGS. 12-16. As sidewall portion 124-2 can have more exposure to etchants than top and bottoms portions 124-1 and 124-3 during subsequent etching processes, crystallized sidewall portions 124-2 can prevent gate dielectric layer 124 from high-k damage and can reduce leakage current. In some embodiments, the subsequent etching processes can remove amorphous high-k dielectric materials but may not remove crystalline high-k dielectric materials.

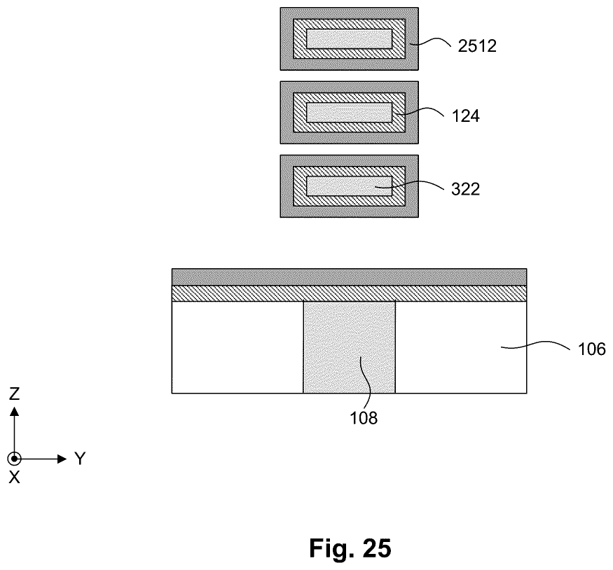

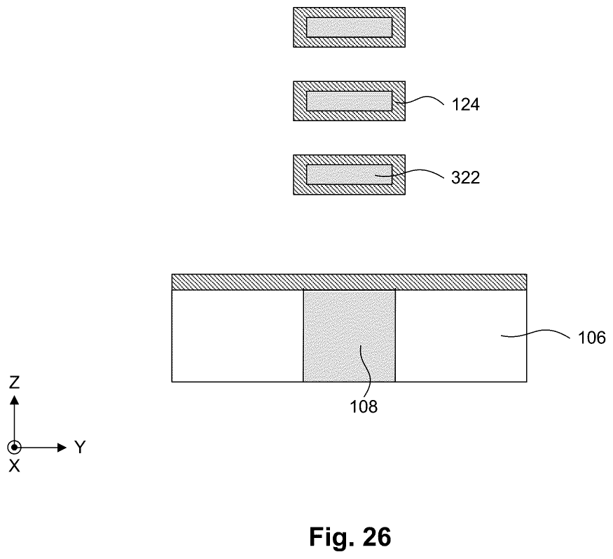

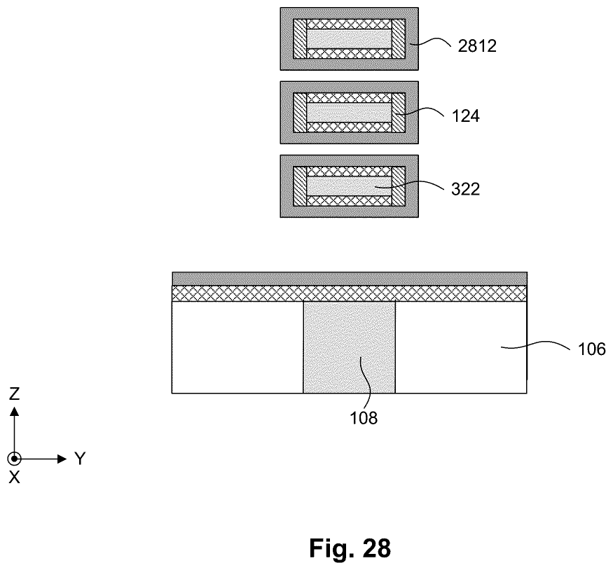

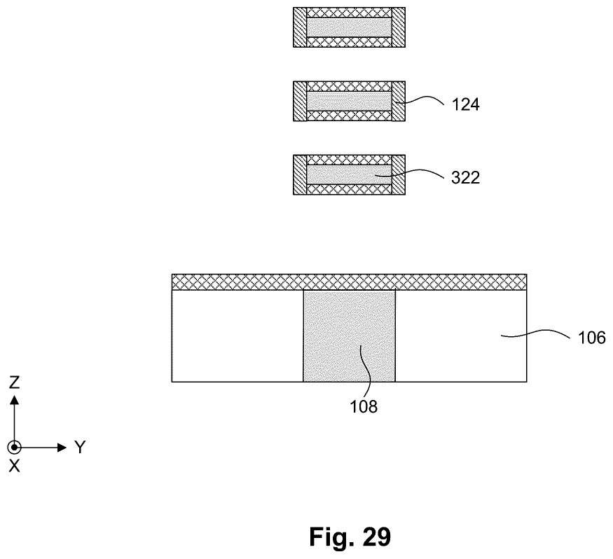

Referring to FIG. 22, in operation 2240, a gate structure is formed on the high-k gate dielectric layer. For example, as shown in FIGS. 3, 25, 26, 28, and 29, gate structures 112 can be formed on gate dielectric layer 124. In some embodiments, the formation of gate structures 112 can be similar to the process described in operation 550. In some embodiments, as shown in FIGS. 25 and 28, work function layers 2512 and 2812 can be deposited on gate dielectric layer 124 by ALD, CVD, PVD, e-beam deposition, or other suitable deposition methods. In some embodiments, as shown in FIGS. 26 and 29, work function layers 2512 and 2812 can be removed in subsequent etching processes to form transistors with a certain Vₜ. After the formation of additional work function layers and the metal fill, gate structures 112 can be formed on gate dielectric layer 124 wrapping around nanostructures 322, as shown in FIG. 3.

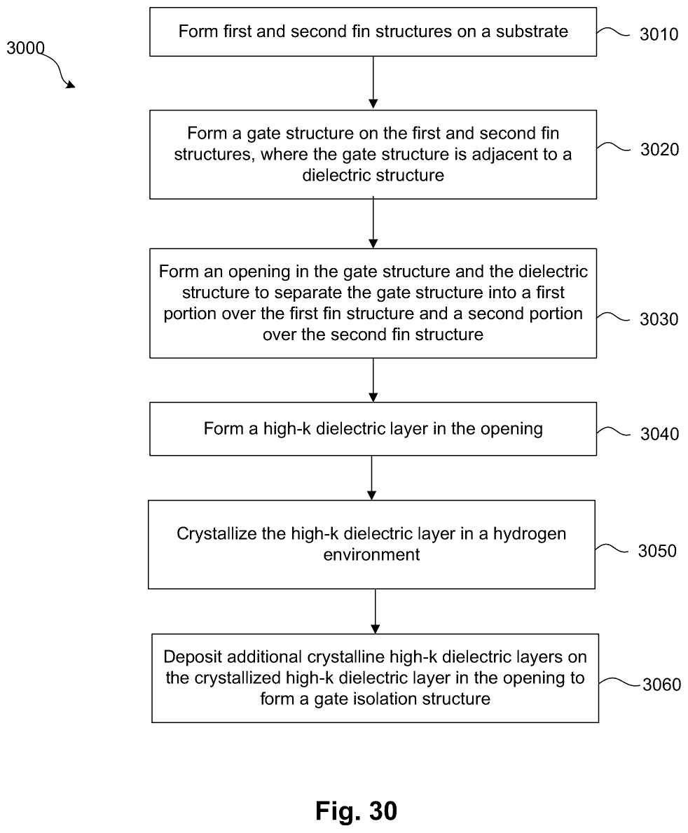

FIG. 30 is a flow diagram of a method 3000 for fabricating semiconductor device 100 having a crystalline high-k dielectric layer, in accordance with some embodiments. Method 3000 may not be limited to finFET or nanostructure transistor devices and can be applicable to other devices that would benefit from the crystalline high-k dielectric layer. Additional fabrication operations may be performed between various operations of method 3000 and may be omitted merely for clarity and ease of description. Additional processes can be provided before, during, and/or after method 3000; one or more of these additional processes are briefly described herein. Moreover, not all operations may be needed to perform the disclosure provided herein. Additionally, some of the operations may be performed simultaneously or in a different order than shown in FIG. 30. In some embodiments, one or more other operations may be performed in addition to or in place of the presently-described operations.

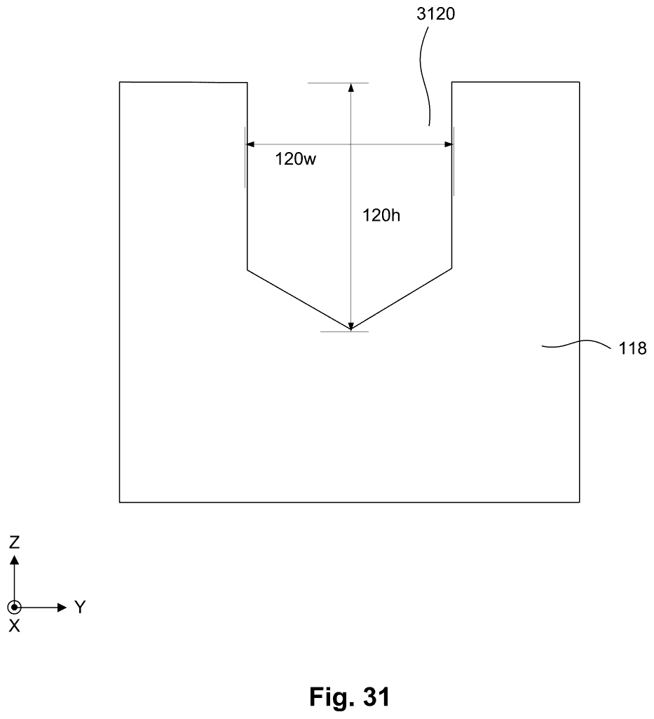

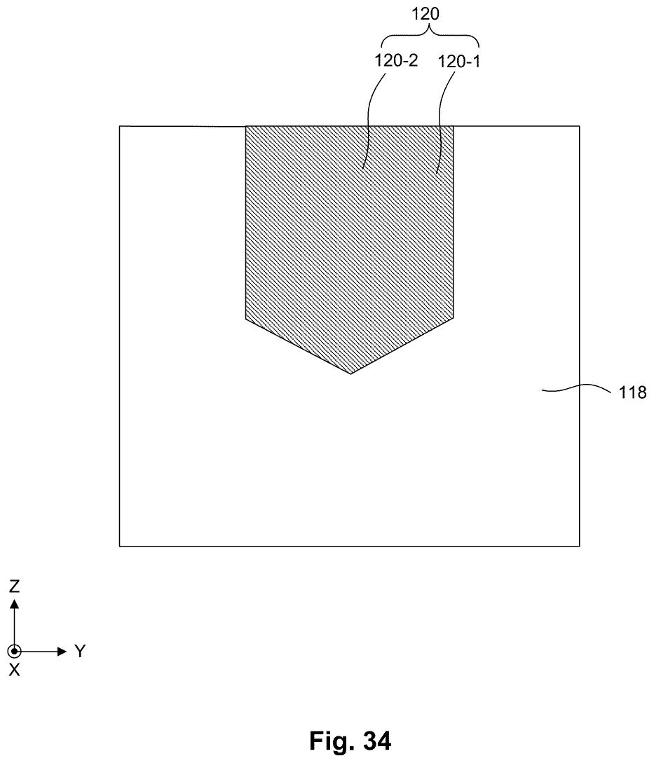

For illustrative purposes, the operations illustrated in FIG. 30 will be described with reference to the example fabrication process for fabricating semiconductor device 100 as illustrated in FIGS. 31-34. FIGS. 31-34 illustrate partial cross-sectional views along line B-B of semiconductor device 100 shown in FIG. 1 at various stages of its fabrication, in accordance with some embodiments. In some embodiments, semiconductor device 100 can have a crystalline high-k dielectric layer in gate isolation structure 120. Elements in FIGS. 31-34 with the same annotations as elements in FIGS. 1-4 are described above.

In referring to FIG. 30, method 3000 begins with operation 3010 and the process of forming first and second fin structures on a substrate. For example, as shown in FIG. 1, first and second fin structures 108 can be formed on substrate 104 and. In some embodiments, the process to form first and second fin structures 108 can be similar to the process described in operation 510.

Referring to FIG. 30, in operation 3020, a gate structure is formed on the first and second fin structures. The gate structures are adjacent to a dielectric structure. For example, as shown in FIG. 1, gate structures 112 can be formed on fin structures 108. Gate structures 112 can be adjacent to ILD layer 118. In some embodiments, the process to form gate structures 112 can be similar to the process described in operation 550.

Referring to FIG. 30, in operation 3030, an opening is formed in the gate structures and the dielectric structure to separate the gate structure into a first portion over the first fin structure and a second portion over the second fin structure. For example, as shown in FIGS. 1 and 31, opening 3120 can be formed in gate structures 112 and ILD layer 118 to separate gate structures 112 into a first portion on one side of opening 3120 over one fin structure 108 and a second portion on an opposite side of opening 3120 over an adjacent fin structure 108. In some embodiments, opening 3120 can be formed by a directional etching process. In some embodiments, opening 3120 can have width 120w along a Y-axis ranging from about 5 nm to about 50 nm and height 120h along a Z-axis ranging from about 50 nm to about 200 nm.

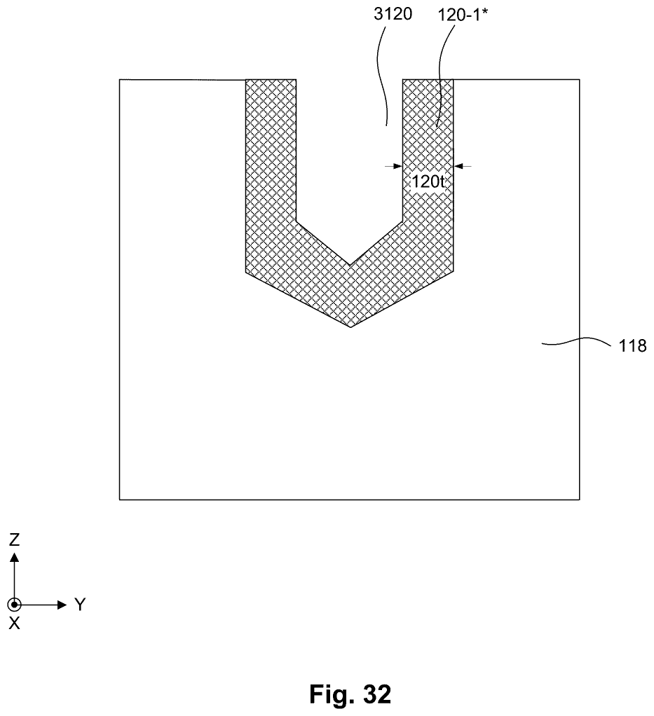

Referring to FIG. 30, in operation 3040, a high-k dielectric layer is formed in the opening. For example, as shown in FIG. 32, high-k dielectric layer 120-1* can be formed in opening 3120. In some embodiments, high-k dielectric layer 120-1* can be conformally deposited in opening 3120 by ALD, CVD, or other suitable deposition methods. In some embodiments, high-k dielectric layer 120-1* can have a thickness 120t ranging from about 0.1 nm to about 5 nm to keep deposited high-k dielectric layer 120-1* amorphous. In some embodiments, deposited high-k dielectric layer 120-1* needs to be fully amorphous to achieve uniform crystallization in the subsequent crystallization treatment. If thickness 120t is greater than about 5 nm, high-k dielectric layer 120-1* may have partially amorphous high-k dielectric material mixed with crystalline high-k dielectric material, which can have a higher leakage current and a lower etch-resistance. If thickness 120t is less than about 0.1 nm, deposited high-k dielectric layer 120-1* may not be uniform.

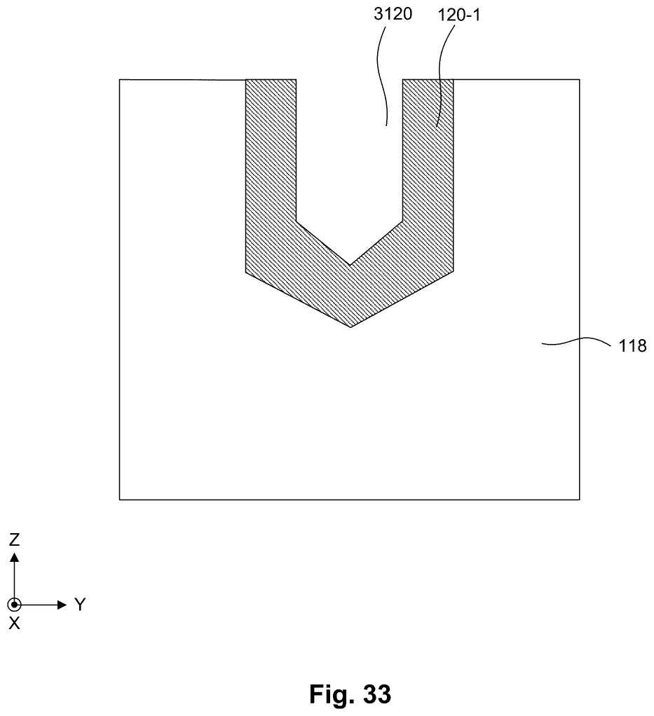

Referring to FIG. 30, in operation 3050, the high-k dielectric layer is crystallized in a hydrogen environment. For example, as shown in FIG. 33, high-k dielectric layer 120-1 can be crystallized by an anneal process with hydrogen radicals or hydrogen gases, as described in detail in FIGS. 17-21. In some embodiments, high-k dielectric layer 120-1 can be crystallized by directional and tilted hydrogen plasma 750, as described in detail in FIGS. 7-16.

Referring to FIG. 30, in operation 3060, additional crystalline high-k dielectric layers are deposited on the crystallized high-k dielectric layer in the opening to form a gate isolation structure. For example, as shown in FIGS. 1, 4, and 34, crystalline high-k dielectric layer 120-2 can be deposited on crystallized high-k dielectric layer 120-1 in opening 3120 to form gate isolation structure 120. In some embodiments, high-k dielectric layer 120-2 can be conformally deposited on crystallized high-k dielectric layer 120-1 by ALD, CVD, or other suitable deposition methods. In some embodiments, additional high-k dielectric material deposited on crystallized high-k dielectric layer 120-1 can maintain crystalline due to the crystalline high-k dielectric material in high-k dielectric layer 120-1. In some embodiments, the crystalline high-k dielectric material in gate isolation structure can improve its etch resistance, reduce high-k damage, and reduce leakage current.

Various embodiments in the present disclosure provide example methods for forming crystalline high-k dielectric layers 213, 215, 124, and 120 in semiconductor device 100. In some embodiments, semiconductor device 100 can include fin structures 108 on substrate 104, gate dielectric layer 124 on fin structures 108, and gate structures 112 on gate dielectric layer 124. Top portions 213-1 and 215-1 of gate dielectric layer 124 can be crystalline and can include a crystalline high-k dielectric material. In some embodiments, semiconductor device 100 can include nanostructures 322 on substrate 204, gate dielectric layer 124 wrapped around nanostructures 322, and gate structures 112 wrapped around gate dielectric layer 124. Sidewall portion 124-2 of gate dielectric layer 124 can be crystalline and can include a crystalline high-k dielectric material. In some embodiments, top, sidewall, and bottom portions of gate dielectric layer 124 can be crystalline and can include a crystalline high-k dielectric material. In some embodiments, semiconductor device 100 can further include gate isolation structure 120. Gate isolation structure 120 can be crystalline and can include crystalline high-k dielectric layer 120-1. In some embodiments, crystalline high-k dielectric layers 213, 215, 124, and 120-1 can be formed by a treatment in a hydrogen environment, such as a hydrogen plasma treatment or an anneal with hydrogen radicals or hydrogen gases. With crystalline high-k dielectric layers 213, 215, 124, and 120-1, gate dielectric layer 124 and the gate isolation structure 120 can have reduced leakage current and improved etch-resistance.

In some embodiments, a semiconductor structure includes a fin structure on a substrate, a gate dielectric layer on the fin structure, and a gate structure on the gate dielectric layer. A top portion of the gate dielectric layer includes a crystalline high-k dielectric material.

In some embodiments, a semiconductor structure includes first and second fin structures on a substrate, a first gate structure disposed on the first fin structure, a second gate structure disposed on the second fin structure, a dielectric structure adjacent to the first and second gate structure, and a gate isolation structure within the dielectric structure and separating the first and second gate structures. The gate isolation structure includes a crystalline high-k dielectric material.

In some embodiments, a method includes forming a fin structure on a substrate, forming a first high-k gate dielectric layer on the fin structure, crystallizing a portion of the first high-k gate dielectric layer in a hydrogen environment, forming a second high-k gate dielectric layer on the first high-k gate dielectric layer, and forming a gate structure on the second high-k gate dielectric layer.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a fin structure on a substrate;
a gate dielectric layer on the fin structure, wherein a top portion of the gate dielectric layer is crystalline and comprises a crystalline high-k dielectric material; and
a gate structure on the gate dielectric layer.

2. The semiconductor structure of claim 1, wherein sidewall portions of the gate dielectric layer are crystalline and comprise the crystalline high-k dielectric material.

3. The semiconductor structure of claim 1, wherein sidewall portions of the gate dielectric layer are amorphous and comprise an amorphous high-k dielectric material.

4. The semiconductor structure of claim 1, wherein a thickness of the gate dielectric layer ranges from about 0.1 nm to about 5 nm.

5. The semiconductor structure of claim 1, further comprising an additional gate dielectric layer between the gate dielectric layer and the gate structure, wherein a top portion of the additional gate dielectric layer is crystalline and comprises an additional crystalline high-k dielectric material different from the crystalline high-k dielectric material.

6. The semiconductor structure of claim 5, wherein sidewall portions of the additional gate dielectric layer are crystalline and comprise the additional crystalline high-k dielectric material.

7. The semiconductor structure of claim 5, wherein sidewall portions of the additional gate dielectric layer are amorphous and comprise an additional amorphous high-k dielectric material.

8. The semiconductor structure of claim 5, wherein a ratio of the thickness of the gate dielectric layer to the thickness of the additional gate dielectric layer ranges from about 5 to about 15.

9. A semiconductor structure, comprising:
one or more nanostructures on a substrate;
a gate dielectric layer wrapped around the one or more nanostructures, wherein sidewall portions of the gate dielectric layer are crystalline and comprise a crystalline high-k dielectric material; and
a gate structure surrounding the gate dielectric layer.

10. The semiconductor structure of claim 9, wherein top and bottom portions of the gate dielectric layer are crystalline and comprise the crystalline high-k dielectric material.

11. The semiconductor structure of claim 9, wherein top and bottom portions of the gate dielectric layer are amorphous and comprise an amorphous high-k dielectric material.

12. The semiconductor structure of claim 9, further comprising an additional gate structure and a gate isolation structure separating the gate structure and the additional gate structure, wherein the gate isolation structure is crystalline and comprises the crystalline high-k dielectric material.

13. A method, comprising:
forming a fin structure on a substrate;
forming a first high-k gate dielectric layer on the fin structure;
crystallizing a portion of the first high-k gate dielectric layer in a hydrogen environment;
forming a second high-k gate dielectric layer on the first high-k gate dielectric layer; and
forming a gate structure on the second high-k gate dielectric layer.

14. The method of claim 13, wherein crystallizing the portion of the first high-k gate dielectric layer comprises crystallizing a top portion of the first high-k gate dielectric layer.

15. The method of claim 13, wherein crystallizing the portion of the first high-k gate dielectric layer comprises crystallizing top and sidewall portions of the first high-k gate dielectric layer.

16. The method of claim 13, wherein crystallizing the portion of the first high-k gate dielectric layer comprises treating the first high-k gate dielectric layer with a hydrogen plasma.

17. The method of claim 13, wherein crystallizing the portion of the first high-k gate dielectric layer comprises annealing the first high-k gate dielectric layer with hydrogen radicals.

18. The method of claim 13, wherein crystallizing the portion of the first high-k gate dielectric layer comprises annealing the first high-k gate dielectric layer with a hydrogen gas.

19. The method of claim 13, wherein the first high-k gate dielectric layer comprises a first high-k dielectric material and the second high-k gate dielectric layer comprises a second high-k dielectric material different from the first high-k dielectric material.

20. The method of claim 13, further comprising crystallizing a portion of the second high-k gate dielectric layer in the hydrogen environment.
